(19) United States
(12) Patent Application Publication
(10) Pub. No.: US 2006/0159290 A1
(43) Pub. Date: Jul. 20, 2006

(54) Microphone and 2nd amplifier on and off foot switch

(76) Inventor: Christopher Arthur Attard, E. Patchogue, NY (US)

Correspondence Address: Chritopher Arthur Attard, 146 PINENECK AVE, E. Patchogue, New York, NY, 11772, US

(21) Appl. No.: 11/035,919

(22) Filed: Jan. 15, 2005

(51) Int. Cl. G10H 1/00; H03F 21/00

(52) U.S. Cl. 381/118; 381/120

(57) ABSTRACT

The microphone and 2nd amplifier on and off foot switch is and does exactly what its title is and says it does. With a microphone plugged into this foot switch and out to the P.A. system; stepping on the foot switch will turn the microphone on or off. So while the microphone is in front of a soloist musician's amplifier; stepping on the foot switch which I intend to call The Soundman Box will send his or her sound right through the P.A. system at almost recording studio quality volume. The 2nd amplifier switch is for when a musician has an effects system with stereo output which will go mono to 1 amplifier and the remaining output will go through the foot switch and out to his or her 2nd amplifier which will be turned on and off in the same manner.

### BACKGROUND OF THE INVENTION

The microphone and 2nd amplifier on and off foot switch is related to the music field and is designed for the guitar player, keyboard player, or any other lead player (sax Etc.). The D.O.D. Company came out years ago with a devise inspired by Eric Clapton called an “A-B box”. This devise is somewhat related to mine.

### BRIEF SUMMARY OF THE INVENTION

The microphone and 2nd amplifier on and off foot switch is a simple foot pedal with 2 switches. One switch is for a microphone and one switch is for another microphone or a 2nd amplifier. Stepping on either switch simply turns the signal going to the P.A. system on and off. I will now give you just one example of the usage and the idea of this invention.

A guitar player is playing in a small club with a band. He is playing out of his own amplifier. There is a microphone set in front of the amplifier which is connected to the foot switch leading to the P.A. system though the foot switch is set to off at this time. The microphone volume level is set at the musician's desired level. He steps on the foot switch turning on the microphone and therefor broadening his volume throughout the room. He is now playing in at recording studio quality. When the solo finishes, he simply turns the microphone off by stepping on the foot switch.

### BRIEF DESCRIPTION OF THE SEVERAL VIEWS OF THE DRAWING

FIG. 1 is a front view of the foot switch. The drawing obviously shows the 2 switches to step on. This view also shows input connections on the left side which are XLR and quarter inch mono phono connectors. The rectangular casing is made of A.S.B. hard plastic. The actual dimensions are 6 inch by 4 inch by 1 and a half-inch depth.

FIG. 2 shows the foot switch turned to the left side which clearly shows the quarter inch mono phono input and the 3 pin XLR female panel mount input. On top you can see the 2 push on/push off switches. The rectangle casing is made of A.S.B. hard plastic and has the same dimensions as described in FIG. 1.

FIG. 3 shows the foot switch turned to the right side which clearly shows the quarter inch mono phono output and the 3 pin XLR male panel mount output. Again, you can see the 2 push on/push off switches on top. The rectangle casing is made of A.S.B. hard plastic and has the same dimensions as described in FIG. 1.

FIG. 4 shows a view of the foot switch upside down with the bottom plate removed to show connections inside. The quarter inch mono phono connectors (bottom left and right) are each wired to the switch from their leads and wired to each other from the ground. The 3 pin XLR male and female connectors (top left and right) has pin number 2 for both connectors which is wired to the push-on/push-off switch and has the remaining 2 pins for both connectors (numbers 1 and 3) which are wired to each other. The rectangular casing is made of A.S.B. hard plastic and has the same dimensions as described in FIG. 1.

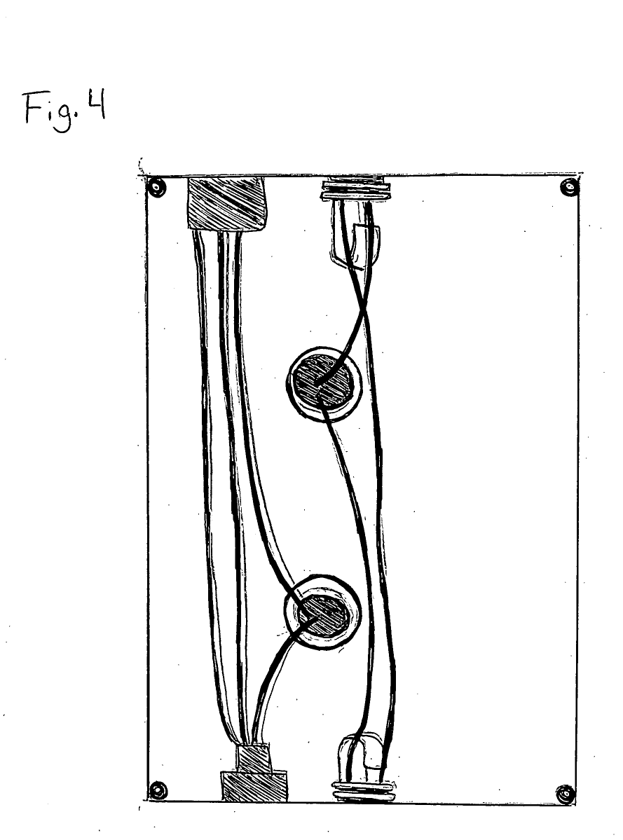

### DETAILED DESCRIPTION OF THE INVENTION

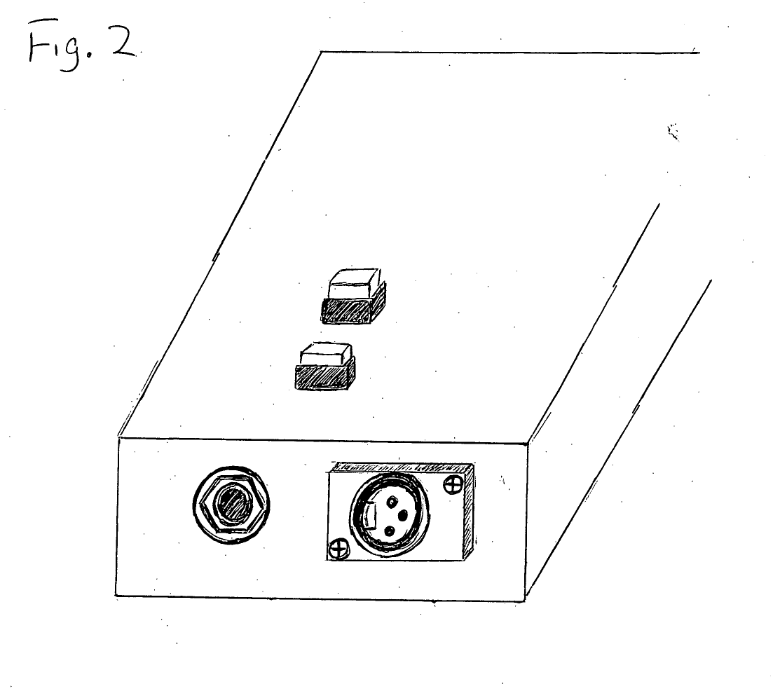

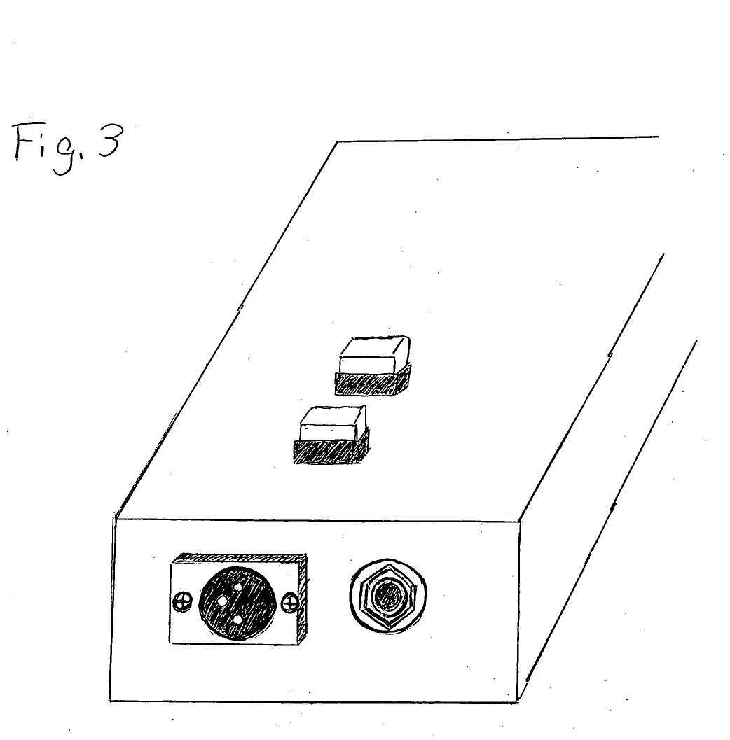

The microphone and 2nd amplifier on and off foot switch which I intend to call The Soundman Box will be a rectangular-shaped box made of A.B.S. plastic 6 inches by 4 inches by depth of one and a half inches. There will be 2 push-on/push-off switches which will turn the signal going from the XLR input and output or the signal going from the quarter-inch mono phono input and output (see FIGS. 2 and 3 for connectors and all 4 figures for switches and casing) on and off.

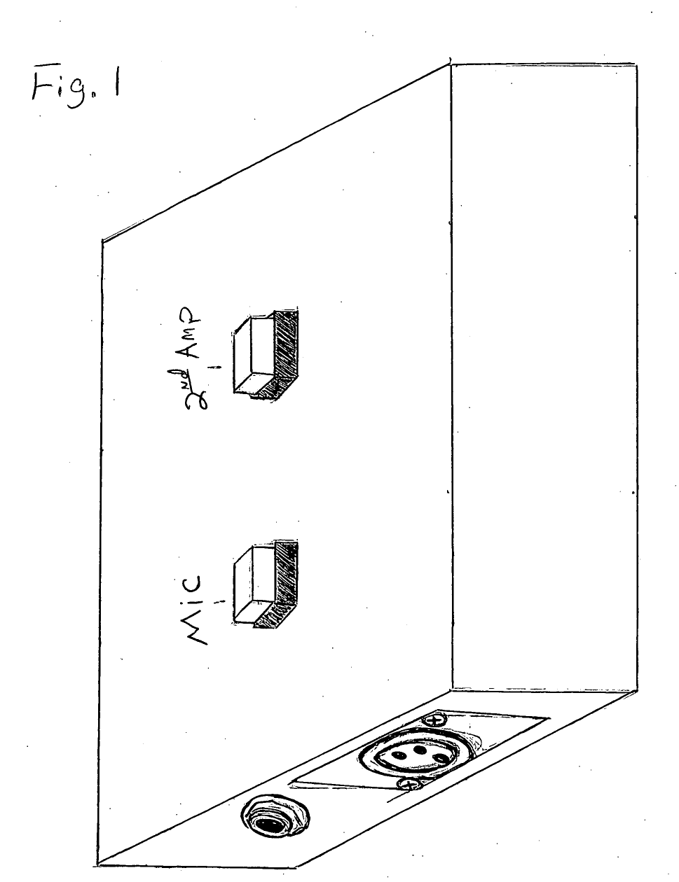

The way to use the foot switch would simply be to plug a microphone to the XLR input (see FIG. 2) and an XLR cable to the XLR out (see FIG. 3) running to the P.A. system. Then when necessary, by stepping on the left push-on/push-off switch (see FIG. 1), the signal can be turned on and off which obviously turns the microphone on and off. For example, a guitar player can use this foot switch for a live gig with a band. He simply puts a microphone in front of his amplifier connected to the foot switch and to the P.A. system at a desired volume level. For most of the time the microphone is off until a solo or other desired moment where he needs to be heard at recording studio quality. He then simply turns on the microphone by stepping on the foot switch which will send his amplified sound right through the P.A. system at the set P.A. volume in addition to his amplifier volume. The quarter inch mono phono input and output is for the right push-on/push-off switch (see FIG. 1) which can be used for a microphone that connects with a quarter inch jack.

This device can be used for a 2nd amplifier coming from a stereo effects output which is mainly used by guitar players. This foot switch can also be used by the musician for any other combination of sound techniques that his or her imagination can come up with.

1. What I claim as my invention is the microphone and 2nd amplifier on and off foot switch.

2. The foot switch of claim 1 wherein said foot switch will be of A.S.B. hard plastic or metal rectangular shaped casing 6 inch by 4 inch by 1 and a half inch depth with 2 available push-on/push-off switches on top of casing. One switch for the XLR input and output availability and the other switch for quarter inch mono phono input and output availability.

3. The foot switch of claim 2 wherein said all input output connectors and both push-on/push-off switches are self-fastened to casing with screws and nuts electronically soldered together as described in specification.

4. I claim that this invention will take the place of a soundman by using this on and off foot switch to activate a microphone while the microphone is in front of an amplifier which will send the amplified sound through the P.A. system.

5. I claim that this invention will take the place of a soundman also by the foot switch being capable of turning on and off a signal coming from a stereo effects output to a 2nd amplifier activating sound from mono to stereo with use of the foot switch.
